(19) United States
(12) Patent Application Publication
(10) Pub. No.: US 2012/0258566 A1
(43) Pub. Date: Oct. 11, 2012

(54) SUBSTRATE PROCESSING APPARATUS, METHOD FOR MANUFACTURING SOLAR BATTERY, AND METHOD FOR MANUFACTURING SUBSTRATE

(75) Inventors: Eisuke NISHITANI, Toyama-city (JP); Yasuo KUNII, Takasaki-city (JP); Kazuyuki TOYODA, Toyama-city (JP); Hironobu MIYA, Toyama-city (JP)

(73) Assignee: HITACHI KOKUSAI ELECTRIC INC., Tokyo (JP)

(21) Appl. No.: 13/427,419

(22) Filed: Mar. 22, 2012

(30) Foreign Application Priority Data
Apr. 8, 2011 (JP) 2011-086642

(51) Int. Cl. H01L 31/18; C23C 16/455; H01L 21/06

(52) U.S. Cl. 438/95; 438/478; 118/724; 257/E31.027; 257/E21.068

(57) ABSTRACT

There is provide a substrate processing apparatus, comprising: a processing chamber configured to house a plurality of substrates with a laminated film formed thereon which is composed of any one of copper-indium, copper-gallium, or copper-indium-gallium; a gas supply tube configured to introduce elemental selenium-containing gas or elemental sulfur-containing gas into the processing chamber; an exhaust tube configured to exhaust an atmosphere in the processing chamber; and a heating section provided so as to surround the reaction tube, wherein a base of the reaction tube is made of a metal material.

### TECHNICAL FIELD

The present invention relates to a substrate processing apparatus, a method for manufacturing a solar battery, and a method for manufacturing a substrate, and particularly relates to the substrate processing apparatus for forming a light absorbing layer of a selenide-based CIS solar battery, and the method for manufacturing the selenide-based CIS solar battery, and the method for manufacturing a substrate using the same.

### DESCRIPTION OF RELATED ART

The selenide-based CIS solar battery has a structure of sequentially laminating a glass substrate, a metal rear surface electrode layer, a CIS-based light absorbing layer, a high resistance buffer layer, and a window layer. Wherein, the CIS-based optical absorbing layer is formed by selenization of a lamination structure of any one of copper (Cu)/gallium (Ga), Cu/indium (In), or Cu—Ga/In. Thus, the selenide-based CIS solar battery has a characteristic that the substrate can be formed thin and also a manufacturing cost can be reduced, because a film with high light absorption coefficient can be formed without using silicon (Si).

Here, patent document 1 can be given as an example of a device that carries out selenization treatment. A selenization device described in patent document 1 applies selenization treatment to an object by arranging a plurality of flat plate-like objects by a holder at constant intervals in parallel to a longitudinal axis of a cylindrical quartz chamber with its surface level vertical to the objects, to thereby selnide the objects by introducing a selenium source.

### PATENT DOCUMENT 1

Japanese Patent Laid Open Publication No. 2006-186114

### SUMMARY OF THE INVENTION

As described in patent document 1, a quartz chamber (furnace body) is used in a substrate processing apparatus that carries out selenization treatment. However, the quartz chamber involves a problem that its processing is difficult to thereby increase the manufacturing cost and a long-term delivery period is required. Further, the quartz chamber is easily broken, and therefore is difficult to be handled. Particularly, in the CIS solar battery, its substrate is extremely large (300 mm×1200 mm in patent document 1), and therefore the furnace body itself needs to be large, thus further remarkably showing the aforementioned problem.

Therefore, an object of the present invention is to provide a substrate processing apparatus having a furnace body that can be easily processed, compared with a quartz chamber, and further provide a chamber easy to be handled, compared with the quartz chamber.

According to a first aspect of the present invention, there is provided a substrate processing apparatus, comprising:
a processing chamber in which a plurality of substrates are housed, each of the plurality of substrates having a laminated film composed of any one of copper-indium, copper-gallium, or copper-indium-gallium;
a reaction tube provided to constitute the processing chamber;
a gas supply tube configured to introduce elemental selenium-containing gas or elemental sulfur-containing gas into the processing chamber;
an exhaust tube configured to exhaust an atmosphere of the processing chamber; and
a heating section provided to surround the reaction tube,
wherein a material of base of the reaction tube is made of a metal material.

According to other aspect of the present invention, there is provided a method for manufacturing a substrate, or a method for manufacturing a CIS-based solar battery, comprising:
loading a plurality of substrates each of which has a laminated film composed of any one of copper-indium, copper-gallium, or copper-indium-gallium, into a reaction tube with its base made of a metal material;
processing the plurality of substrates by heating the processing chamber and introducing elemental selenium-containing gas or elemental sulfur-containing gas to the processing chamber, for selenization or sulfurization the plurality of substrates; and
unloading the plurality of substrates after exhausting the elemental selenium-containing gas or the elemental sulfur-containing gas in the processing chamber.

A furnace body that can be easily processed compared with the quartz chamber can be realized. Further, the furnace body easy to be handled compared with the quartz chamber can be realized.

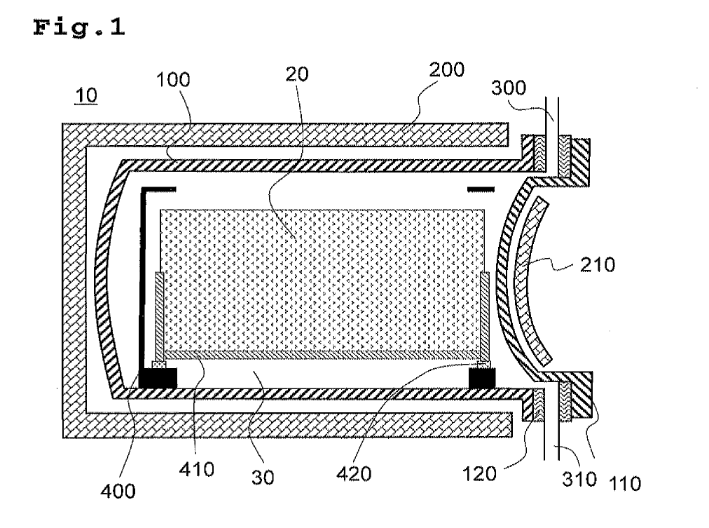

FIG. 1 is a side cross-sectional view of a processing furnace according to a first embodiment of the present invention.

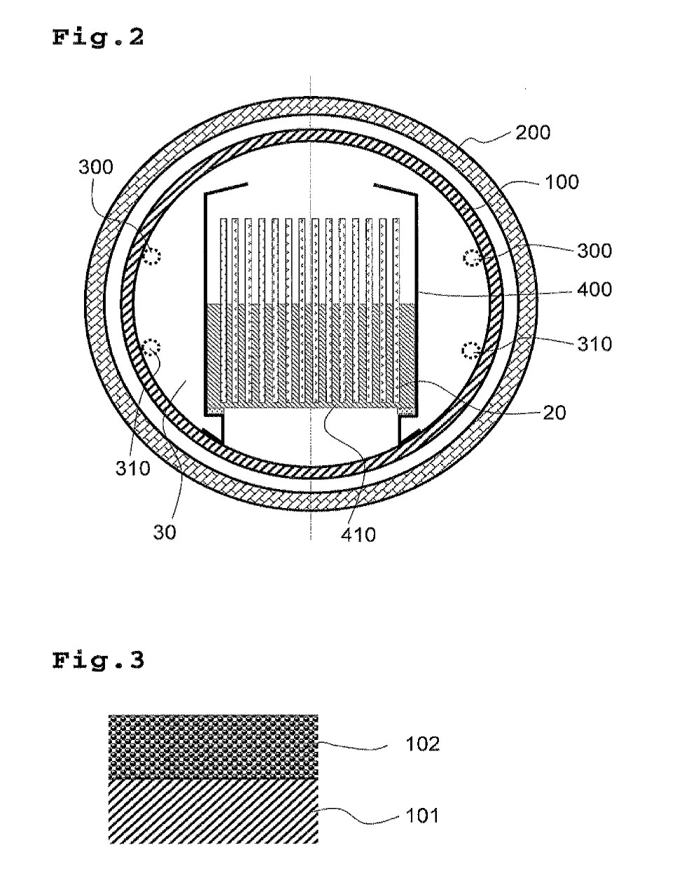

FIG. 2 is a cross-sectional view of the processing furnace viewed from a left direction on the paper of FIG. 1.

FIG. 3 is a view describing a coating film according to a first embodiment of the present invention.

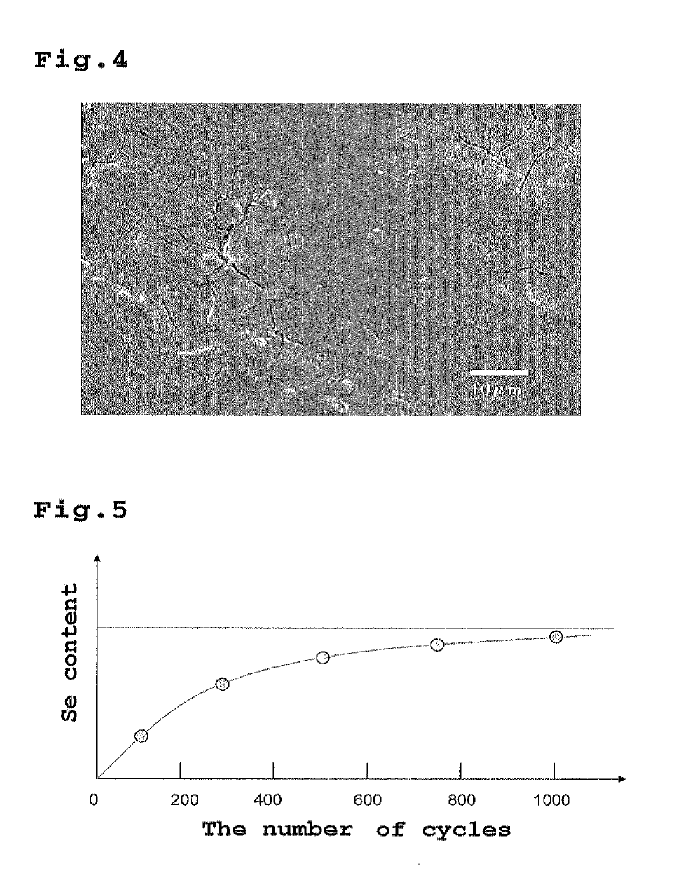

FIG. 4 is an SEM photograph after applying selenization treatment to a surface of the coating film of the present invention.

FIG. 5 is a view describing an effect due to a difference of deviation of the coefficient of linear expansion between the coating film and a base of a reaction furnace of the present invention.

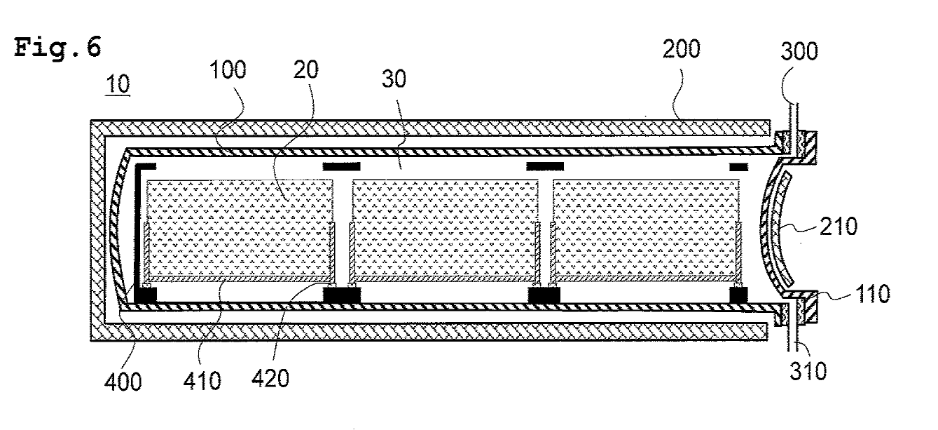

FIG. 6 is a side cross-sectional view of the processing furnace according to a second embodiment of the present invention.

### DETAILED DESCRIPTION OF THE INVENTION

### First Embodiment

Embodiments of the present invention will be described next, with reference to the drawings. FIG. 1 is a side cross-sectional view of a processing furnace 10 assembled into a substrate processing apparatus that performs selenization treatment according to the present invention. Further, FIG. 2 is a cross-sectional view of the processing furnace viewed from a left side on the paper of FIG. 1.

The processing furnace 10 has a reaction tube 100, being a furnace body, made of a metal material such as stainless. The reaction tube 100 has a hollow cylindrical shape, with its one end closed and the other end opened. A processing chamber 30 is formed by the hollow portion of the reaction tube 100. A cylindrical shaped manifold 120 with its both ends opened, is provided concentrically with the reaction tube 100, on the opening part side of the reaction tube 100. An O-ring (not shown), being a seal member, is provided between the reaction tube 100 and the manifold 120.

A movable seal cap 110 is provided in the opening part of the manifold 120 where the reaction tube 100 is not provided. The seal cap 110 is made of a metal material such as stainless, and has a projection shape so as to be partially inserted into the opening part of the manifold 120. The O-ring, being the seal member, (not shown) is provided between the movable seal cap 110 and the manifold 120, and when the processing is performed, the seal cap 110 air-tightly closes the opening part side of the reaction tube 100.

An inner wall 400 is provided inside the reaction tube 100, for placing a cassette 410 which holds a plurality of glass substrates (for example 30 to 40 glass substrates) with a laminated film formed thereon. The laminated film is composed of copper (Cu), indium (In), and gallium (Ga). As shown in FIG. 3, the inner wall 400 is formed so that one end thereof is fixed to an inner circumferential surface of the reaction tube 100, and the cassette 410 is placed in the center of the reaction tube 100 via an installation base 420. The inner wall 400 is formed so that a pair of members provided in such a manner as interposing the cassette 410 between them, are connected to each other at both ends, thus increasing the strength thereof. As shown in FIG. 1, the cassette 410 has holding members capable of holding a plurality of glass substrates 20 in an upright state arranged in a horizontal direction, at both ends of the glass substrates 20. Further, the holding members at both ends are fixed by a pair of fixing bars provided on the lower side of the holding member, and lower ends of the plurality of glass substrates are exposed to the inside of the reaction chamber. Note that the fixing bar for fixing the both ends of the cassette 410 may be provided on the upstream side of the holding members at both ends to increase the strength of the cassette 410.

Further, a furnace heating section 200 having a hollow cylindrical shape is provided, with one end closed and the other end opened to surround the reaction tube 100. Further, a cap heating section 210 is provided on a side face opposite to the reaction tube 100 of the seal cap 110. Inside of the processing chamber 30 is heated by the furnace heating section 200 and the cap heating section 210. Note that the furnace heating section 200 is fixed to the reaction tube 100 by a fixing member not shown, and the cap heating section 210 is fixed to the seal cap 110 by the fixing member not shown. Further, a cooling unit such as a water cooling unit not shown is provided in the seal cap 110 and the manifold 120, for protecting the O-ring having low heat resistance.

A gas supply tube 300 is provided in the manifold 120, for supplying selenium hydride (“H₂Se” hereafter), being elemental selenium-containing gas (selenium source). H₂Se supplied from the gas supply tube 300 is supplied to the processing chamber 30 via a space between the manifold 120 and the seal cap 110. Further, an exhaust tube 310 is provided at a different position from the gas supply tube 300 of the manifold 120. The atmosphere in the processing chamber 30 is exhausted from the exhaust tube 310 via the space between the manifold 120 and the seal cap 110. Note that if a cooling spot is cooled to 150° C. or less by the aforementioned cooling unit, unreacted selenium is condensed at this spot, and therefore temperature may be controlled from about 150° C. to 170° C.

The reaction tube 100 is made of the metal material such as stainless. The metal material such as stainless is easy to be processed, compared with quartz. Therefore, a large-sized reaction tube 100 used for the substrate processing apparatus that applies selenization treatment to the CIS solar battery, can be easily manufactured. The number of the glass substrates that can be housed in the reaction tube 100 can be increased, and therefore the manufacturing cost of the CIS solar battery can be reduced.

Further, in this embodiment, as shown in FIG. 3, at least the surface of the reaction tube 100 exposed to the atmosphere in the processing chamber 30, is coated with a coating film formed on the metal material such as stainless, being a base 101, as shown in FIG. 4, with high selenization resistance compared with the metal material such as stainless. A generally used metal material such as stainless has extremely high reactivity and accelerates corrosion by heating the gas such as H₂Se at 200° C. or more. However, by forming the coating film with high selenization resistance like this embodiment, the corrosion by the gas such as H₂Se can be suppressed, and therefore the generally used metal material such as stainless can be used. Thus, the manufacturing cost of the substrate processing apparatus can be reduced. Note that the coating film mainly composed of ceramic is preferable as the coating film with high selenization resistance, and chromium oxide (CrₓO_{y}: x, y are arbitrary number of 1 or more), alumina (AlₓO_{y}: x, y are arbitrary number of 1 or more), silica (SiₓO_{y}: x, y are arbitrary number of 1 or more) alone respectively or a mixture of them, for example silicon carbide (SiC) and diamond-like carbon (DLC) can be given.

Further, a coating film 102 of this embodiment is formed by a porous film. Thus, thermal expansion/contraction can be flexibly coped with, which is caused by a difference of coefficient of linear expansion between the base 101 formed by the metal material such as stainless and the coating film 102. As a result, even if heat treatment is repeatedly performed, generation of a crack on the coating film can be suppressed to minimum. Note that the coating film 102 is desirably formed in a thickness of 2 to 200 μm, and more preferably 50 to 120 μm. Further, deviation of the coefficient of linear expansion between the base 101 and the coating film 102 is preferably 20% or less, and more preferably 5% or less.

Further, the aforementioned coating film may also be similarly formed on a part of the seal cap 110, the manifold 120, the gas supply tube 300, and the exhaust tube 310 exposed to a selenium source. However, coating may not be applied to a part cooled to 200° C. or less by a cooling unit for protecting the O-ring, etc., because the metal material such as stainless is not reacted even if it is brought into contact with the selenium source.

Next, explanation will be given for a method for manufacturing substrates, being a part of the method for manufacturing the CIS-based solar battery, using the processing furnace of this embodiment.

First, 30 to 40 glass substrates with a laminated film composed of copper (Cu), indium (In), and gallium (Ga), are prepared in the cassette 410, and the cassette 410 is loaded into the processing chamber 30 in a state that a movable seal cap 110 is removed from the manifold 120 (loading step). Loading of the cassette is performed, for example, in such a way that a lower part of the cassette is supported by the arm of a loading/unloading device not shown, and in a lifting state, the cassette 410 is moved into the processing chamber 30, and after the cassette 410 reaches a prescribed position, the arm is moved below, to thereby place the cassette 410 on an installation base 420.

Thereafter, inside of the processing chamber 30 is replaced with inert gas such as nitrogen gas (replacement step). After the atmosphere in the processing chamber 30 is replaced with the inert gas, in a normal temperature state, the selenium source such as H₂Se gas diluted to 1 to 20% (preferably 2 to 20%) by the inert gas, is introduced from the gas supply tube 300. Next, the temperature is increased at a rate of 3 to 50° C. per minute, up to 400 to 550° C. and preferably 450° C. to 550° C. in a state that the selenium source is sealed, or in a state that a constant amount of the selenium source is flowed by exhausting the constant amount of the selenium source from the exhaust tube 310. After the temperature is increased to a prescribed temperature, this state is maintained for 10 to 180 minutes, preferably for 20 to 120 minutes, to thereby carry out selenization treatment so that a light absorbing layer of the CIS-based solar battery is formed (formation step).

Thereafter, the inert gas is introduced from the gas supply tube 300, then the atmosphere in the processing chamber 30 is replaced, and the temperature is decreased to a prescribed temperature (temperature decreasing step). After the temperature is decreased to the prescribed temperature, the processing chamber 30 is opened by moving the seal cap 110, and the cassette 410 is unloaded by the arm of a loading/unloading device not shown (unloading step), to thereby end a series of processing.

As an acceleration test, FIG. 4 shows the SEM photograph of the surface of the coating film after forming the coating film of the present invention on a stainless (SUS304) base, and carrying out selenization treatment 10 times at 650° C. which is higher than the temperature of the selenization treatment actually carried out. As described above, it is found that a minute crack of several μm to several μm due to repeated heat treatment is generated. However, there is completely no sign of peel-off in its appearance, and it is found that this coating film functions sufficiently.

Further, in order to examine a service life of selenization resistance of the coating film, Se content is evaluated, which is accumulated on an interface and in the coating film due to repeated selenization treatment, and also the Se content is evaluated when an oxide film is changed to a selenide film. FIG. 5 is a view showing a comparison between the number of cycles of the selenization treatment, and the Se content accumulated on the interface and in the coating film or the Se content when the oxide film is changed to the selenide film.

As described in FIG. 4, even in the coating film formed on the SUS 304, there is completely no sign of peel-off, although the minute crack is generated. In FIG. 5 as well, there is completely no sign of peel-off, although the treatment is applied thereto up to 1000 numbers of times at 450° C. Se on the interface shows a saturation tendency, and it is estimated that Se is increased only slightly even if the selenization treatment of more than 1000 numbers of times is carried out. If an operating ratio of the year is taken into consideration, FIG. 5 shows the results of the treatment carried out 1000 numbers of times, which corresponds to the results in a case of carrying out the selenization treatment for about one year as amass production. Here, only the 1000 numbers of times of treatment can be verified. However, there is no fluctuation observed in a coating state even if the number of times of the treatment is increased. Therefore, it is estimated that the coating film has actually several times of service life in principle.

### Second Embodiment

Other embodiment of the processing furnace 10 shown in FIG. 1 and FIG. 2 will be described using FIG. 6. In. FIG. 6, the same signs and numerals are assigned to a member having the same functions as the functions of FIG. 1 and FIG. 2. Further, here, different points from the first embodiment will be mainly described.

In a second embodiment shown in FIG. 6, a different point is that a plurality of cassettes 410 (three in this embodiment) are arranged in a direction parallel to the surface of a plurality of glass substrates, unlike the first embodiment wherein only one cassette 410 that holds the plurality of glass substrates 20 is placed.

In the present invention, not a conventional quartz reaction tube, but the metal material such as stainless, is used as the base of the reaction tube 100. Accordingly, even if the size of the reaction tube 100 is increased, molding of the reaction tube is facilitated compared with the quartz reaction tube, and the increase of the cost is small compared with the cost of the quartz reaction tube. Therefore, the number of glass substrates 20 that can be processed at once, can be increased, and the manufacturing cost of the CIS-based solar battery can be reduced.

Further, by using the metal material such as stainless as the base of the reaction tube, the reaction tube is easy to be handled compared with the quartz reaction tube, and the size of the reaction tube can be increased.

In the present invention according to the first embodiment and the second embodiment, at least one of the following effects can be realized.

(1) The metal material such as stainless is used for the base 101 of the reaction tube. Therefore, the size of the reaction tube 100 is easily increased, and the number of the substrates that can be processed at once can be increased.
(2) In the aforementioned (1), by forming the coating film 102 with high selenization resistance on the base 101 of the reaction tube 100, processing can be performed using a highly corrosive selenium source, and the manufacturing cost of the CIS-based solar battery can be reduced.
(3) In the aforementioned (2), the coating film 102 is formed in a porous shape. Therefore, peel-off of the coating film caused by the deviation of the coefficient of linear expansion between the base 101 and the coating film 102 can be suppressed.
(4) In the aforementioned (2), the deviation of the coefficient of the linear expansion between the base 101 and the coating film 102 is set to preferably 20% or less, and more preferably 5% or less. Therefore, the cycle of maintenance can be made large.
(5) In any one of the aforementioned (1) to (4), a plurality of cassettes 410 holding a plurality of glass substrates 20 are arranged side by side in the direction parallel to the surface of the glass substrates 20. Therefore, the number of the glass substrates that can be processed at once, can be increased, and the manufacturing cost of the CIS-based solar battery can be reduced.

As described above, embodiments of the present invention have been described using the drawings. However, the embodiments can be variously modified in a range not departing from the gist of the present invention. For example, in the aforementioned embodiment, explanation has been given for the selenization treatment applied to a plurality of glass substrates composed of copper (Cu), indium (In), and gallium (Ga). However, the present invention is not limited thereto, and the selenization treatment may also be applied to a plurality of glass substrates composed of copper (Cu)/indium (In) and copper (Cu)/gallium (Ga). Further, this embodiment refers to the selenization treatment which is high in reactivity with the metal material. However, in a case of the CIS-based solar battery, instead of the selenization treatment, or after the selenization treatment, elemental sulfur-containing gas is supplied to carry out sulfidization treatment in some cases. At this time as well, the number of glass substrates capable of carrying out sulfidization treatment at once, can be increased by using a large-sized reaction furnace of this embodiment, and therefore reduction of the manufacturing cost can be realized.

Preferred main aspects of the present invention will be supplementarily described finally.

(1) There is provided a substrate processing apparatus, comprising:
a processing chamber configured to house a plurality of substrates, each of which has a laminated film composed of any one of copper-indium, copper-gallium, or copper-indium-gallium;
a reaction tube provided to constitute the processing chamber;
a gas supply tube configured to introduce elemental selenium-containing gas or elemental sulfur-containing gas into the processing chamber;
an exhaust tube configured to exhaust an atmosphere in the processing chamber; and
a heating section provided to surround the reaction tube,
wherein a base of the reaction tube is made of a metal material.

(2) There is provided the substrate processing apparatus according to the aforementioned (1), comprising a coating film formed on at least a surface exposed to the elemental selenium-containing gas or elemental sulfur-containing gas in the processing chamber side surface of the reaction tube, wherein the coating film has a higher corrosion resistance against the elemental selenium-containing gas, or has a higher corrosion resistance against the elemental sulfur-containing gas than the metal material.

(3) There is provided the substrate processing apparatus according to the aforementioned (2), wherein the coating film is mainly composed of ceramics, or mainly composed of carbon.

(4) There is provided the substrate processing apparatus according to the aforementioned (2) or (3), wherein the coating film is a porous film.

(5) There is provided the substrate processing apparatus according to any one of the aforementioned (2) to (4), wherein deviation of the coefficient of linear expansion between the coating film and the metal material of a base of the reaction tube is 20% or less.

(6) There is provided the substrate processing apparatus according to the aforementioned (5), wherein deviation of the coefficient of linear expansion between the coating film and the metal material of the base of the reaction tube is 5% or less.

(7) There is provided the substrate processing apparatus according to any one of the aforementioned (1) to (6), wherein the metal material of the base of the reaction tube is stainless.

(8) There is provided the substrate processing apparatus according to any one of the aforementioned (1) to (7), wherein a plurality of cassettes are arranged in a direction parallel to the surfaces of the plurality of substrates.

(9) There is provided a method for manufacturing substrates or a method for manufacturing a CIS-based solar battery, comprising:
loading a plurality of substrates with a laminated film composed of any one of copper-indium, copper-gallium, or copper-indium-gallium, into a processing chamber formed inside a reaction tube with its base made of a metal material;
processing the plurality of substrates by heating the processing chamber and introducing elemental selenium-containing gas or elemental sulfur-containing gas into the processing chamber, for selenization or sulfurization of the plurality of substrates; and
unloading the plurality of substrates after exhausting the elemental selenium-containing gas or the elemental sulfur-containing gas in the processing chamber.

What is claimed is:

1. A substrate processing apparatus, comprising:
a processing chamber configured to house a plurality of substrates, each of the plurality of substrate having a laminated film which is composed of any one of copper-indium, copper-gallium, or copper-indium-gallium;
a reaction tube provided to constitute the processing chamber;
a gas supply tube configured to introduce elemental selenium-containing gas or elemental sulfur-containing gas into the processing chamber;
an exhaust tube configured to exhaust an atmosphere in the processing chamber; and
a heating section provided to surround the reaction tube,
wherein a base of the reaction tube is made of a metal material.

2. The substrate processing apparatus according to claim 1, comprising a coating film formed on at least a surface exposed to the elemental selenium-containing gas or elemental sulfur-containing gas in the processing chamber side surface of the reaction tube, wherein the coating film has a higher corrosion resistance against the elemental selenium-containing gas, or has a higher corrosion resistance against the elemental sulfur-containing gas than the metal material.

3. The substrate processing apparatus according to claim 2, wherein the coating film is mainly composed of ceramics, or mainly composed of carbon.

4. The substrate processing apparatus according to claim 2, wherein the coating film is a porous film.

5. The substrate processing apparatus according to claim 2, wherein deviation of the coefficient of linear expansion between the coating film and the metal material of a base of the reaction tube is 20% or less.

6. The substrate processing apparatus according to claim 5, wherein deviation of the coefficient of linear expansion between the coating film and the metal material of the base of the reaction tube is 5% or less.

7. The substrate processing apparatus according to claim 1, wherein the metal material of the base of the reaction tube is stainless.

8. The substrate processing apparatus according to claim 1, wherein a plurality of cassettes are arranged in a direction parallel to the surfaces of the plurality of substrates.

9. A method for manufacturing a CIS-based solar battery, comprising:
loading a plurality of substrates with a laminated film composed of any one of copper-indium, copper-gallium, or copper-indium-gallium, into a processing chamber formed inside a reaction tube with its base made of a metal material;
processing the plurality of substrates by heating the processing chamber and introducing elemental selenium-containing gas or elemental sulfur-containing gas into the processing chamber, for selenization or sulfurization of the plurality of substrates; and
unloading the plurality of substrates after exhausting the elemental selenium-containing gas or the elemental sulfur-containing gas in the processing chamber.

10. A method for manufacturing substrates, comprising:
loading a plurality of substrates with a laminated film composed of any one of copper-indium, copper-gallium, or copper-indium-gallium, into a processing chamber formed inside a reaction tube with its base made of a metal material;
processing the plurality of substrates by heating the processing chamber and introducing elemental selenium-containing gas or elemental sulfur-containing gas into the processing chamber, for selenization or sulfurization of the plurality of substrates; and
unloading the plurality of substrates after exhausting the elemental selenium-containing gas or the elemental sulfur-containing gas in the processing chamber.
